(19) United States
(12) Patent Application Publication
(10) Pub. No.: US 2010/0224252 A1
(43) Pub. Date: Sep. 9, 2010

(54) Photovoltaic Cell Having Multiple Electron Donors

(75) Inventors: Markus Scharber, Linz (AT); Markus Koppe, Marien (AT); Pavel Schilinsky, Bremen (DE); Christoph Josef Brabec, Linz (DE); Stelios A. Choulis, Drapetsona (GR); Gilles Herve Regis Dennler, Tewksbury, MA (US); Hans-Joachim Albert Egelhaaf, Nürnberg (DE); Markus Heinz Biele, Erlangen (DE)

Correspondence Address: FISH & RICHARDSON PC, P.O. BOX 1022, MINNEAPOLIS, MN, 55440-1022, US

(73) Assignee: Konarka Technologies, Inc., Lowell, MA (US)

(21) Appl. No.: 12/717,567

(22) Filed: Mar. 4, 2010

Related U.S. Application Data
(60) Provisional application No. 61/157,604, filed on Mar. 5, 2009.

(51) Int. Cl. H01L 31/00

(52) U.S. Cl. 136/263

(57) ABSTRACT

Photovoltaic cells having multiple electron donors and/or multiple acceptors, as well as related components, modules, systems, and methods, are disclosed.

### CROSS-REFERENCE TO RELATED APPLICATION

Under 35 U.S.C. §119, this application claims priority to U.S. Provisional Patent Application Ser. No. 61/157,604, filed Mar. 5, 2009, the entire contents of which are hereby incorporated by reference.

### TECHNICAL FIELD

This disclosure relates to photovoltaic cells having multiple electron donors and/or multiple acceptors, as well as related components, modules, systems, and methods.

### BACKGROUND

Photovoltaic cells are commonly used to transfer energy in the form of light into energy in the form of electricity. A typical photovoltaic cell includes a photoactive material disposed between two electrodes. Generally, light passes through one or both of the electrodes to interact with the photoactive material to generate electron charge carriers (e.g., electrons or holes).

### SUMMARY

This disclosure is based on the unexpected discovery that incorporating two or more electron donors (e.g., a low bandgap electron donor and a relatively high bandgap electron donor) in a single photoactive layer of a photovoltaic cell can significantly improve the power conversion efficiency (e.g., to at least about 4%) of the photovoltaic cell and can form a photoactive layer with a relatively large thickness (e.g., at least about 150 nm), which is easier and less expensive to manufacture, without sacrificing the charge transfer capability of the photoactive layer.

In one aspect, this disclosure features articles that include a first electrode, a second electrode, and a photoactive layer between the first and second electrodes. The photoactive layer includes an electron donor material and an electron acceptor material. The electron donor material contains a first polymer and a second polymer different from the first polymer. The first polymer includes a first comonomer repeat unit containing a silacyclopentadithiophene moiety or a cyclopentadithiophene moiety and a second comonomer repeat unit containing a benzothiadiazole moiety. The second polymer includes a monomer repeat unit containing a thiophene moiety. The first polymer has a first bandgap. The second polymer has a second bandgap higher than the first bandgap. The article is configured as a photovoltaic cell.

In another aspect, this disclosure features articles that include a first electrode, a second electrode, and a photoactive material between the first and second electrodes. The photoactive material includes an electron donor material and an electron acceptor material. The electron donor material contains a first polymer and a second polymer different from the first polymer. The first polymer includes a first comonomer repeat unit containing a silacyclopentadithiophene moiety or a cyclopentadithiophene moiety and a second comonomer repeat unit containing a benzothiadiazole moiety. The first polymer has a first bandgap. The second polymer has a second bandgap higher than the first bandgap. The article is configured as a photovoltaic cell.

In still another aspect, this disclosure features articles that include a first electrode, a second electrode, and a photoactive material between the first and second electrodes. The photoactive layer has a thickness of at least about 150 nm. The article is configured as a photovoltaic cell. The article has a power conversion efficiency of at least about 4% under AM 1.5 conditions.

Embodiments can include one or more of the following features.

In some embodiments, the first comonomer repeat unit in the first polymer includes a silacyclopentadithiophene moiety of formula (1) or a cyclopentadithiophene moiety of formula (2):

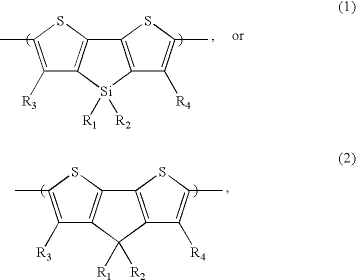

in which each of R₁, R₂, R₃, and R₄, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. In certain embodiments, each of R₁ and R₂, independently, is H, C₁-C₂₀ alkyl, C₁-C₂₀ alkoxy, C₃-C₂₀ cycloalkyl, C₁-C₂₀ heterocycloalkyl, aryl, heteroaryl. For example, each of R₁ and R₂, independently, can be C₁-C₂₀ alkyl (e.g., 2-ethylhexyl or hexyl).

In some embodiments, the second comonomer repeat unit in the first polymer includes a benzothiadiazole moiety of formula (3):

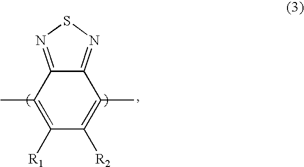

in which each of R₁ and R₂, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. For example, each of R₁ and R₂, independently, can be H.

In some embodiments, the first polymer further includes a third comonomer repeat unit different from the first and second comonomer repeat units. For example, the third comonomer repeat unit can include a silacyclopentadithiophene moiety (e.g., a silacyclopentadithiophene moiety of formula (1) described above) or a cyclopentadithiophene moiety (e.g., a cyclopentadithiophene moiety of formula (2) described above).

In some embodiments, the first polymer includes

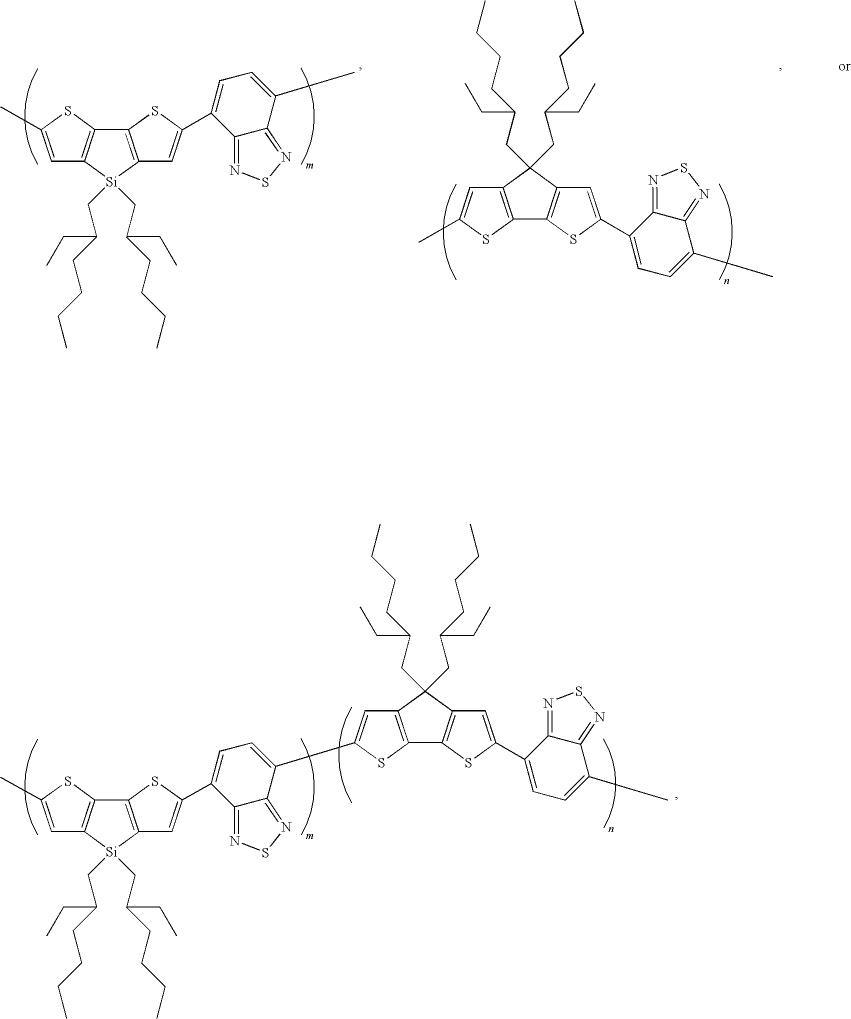

in which n is an integer from 1 to 1,000 and m is an integer from 1 to 1,000.

In some embodiments, the second polymer includes a monomer repeat unit containing a thiophene moiety, such as a thiophene moiety of formula (4):

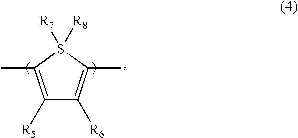

in which each of R₅, R₆, R₇, and R₈, independently, is H, C₁-C₂₀ alkyl (e.g., hexyl), C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. For example, one of R₅ and R₆ can be hexyl. In certain embodiments, the second polymer includes poly(3-hexylthiophene) (P3HT).

In some embodiments, the electron acceptor material includes a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof. For example, the electron acceptor material can include a substituted fullerene, such as [6,6]-phenyl C61-butyric acid methyl ester (C60-PCBM), [6,6]-phenyl C71-butyric acid methyl ester (C70-PCBM), bis(1-[3-(methoxycarbonyl)propyl]-1-phenyl)[6.6]C62 (Bis-C60-PCBM), or 3′Phenyl-3′H-cyclopropa[8,25][5,6]fullerene-C70-bis-D5h(6)-3′ butanoic acid methyl ester (Bis-C70-PCBM). As an example, the chemical structure of Bis-C60-PCBM is shown as

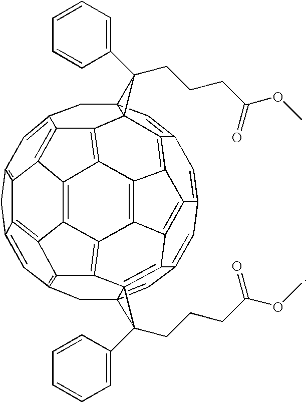

In some embodiments, the weight ratio of the first and second polymers ranges from about 20:1 to about 1:20 (e.g., about 1:4 or about 1:5).

In some embodiments, the first polymer, the second polymer, and the electron acceptor material has a first highest occupied molecular orbital (HOMO) level, a second HOMO level, and a third HOMO level, respectively, and the first HOMO level is between the second and third HOMO levels.

In some embodiments, the first polymer, the second polymer, and the electron acceptor material has a first lowest unoccupied molecular orbital (LUMO) level, a second LUMO level, and a third LUMO level, respectively, and the first LUMO level is between the second and third LUMO levels.

In some embodiments, the weight ratio of the electron donor material and the electron acceptor material ranges from about 1:1 to about 1:3 (e.g., about 1:1).

In some embodiments, the photoactive layer has a thickness of at least about 150 nm.

In some embodiments, the article has a power conversion efficiency of at least about 4% under AM 1.5 conditions.

Embodiments can provide one or more of the following advantages.

Without wishing to be bound by theory, it is believed that including (e.g., blending) both one or more low bandgap semiconducting polymers (e.g., the first polymer described above) and one or more relatively high bandgap semiconducting polymers (e.g., the second polymer described above) in a single photoactive layer of a photovoltaic cell can significantly improve the power conversion efficiency of the photovoltaic cell (e.g., to at least about 4%).

Without wishing to be bound by theory, it is believed that including (e.g., blending) both one or more low bandgap semiconducting polymers (e.g., the first polymer described above) and one or more relatively high bandgap semiconducting polymers (e.g., the second polymer described above) in a single photoactive layer of a photovoltaic cell provides an advantage over including these semiconducting polymers in two separate photoactive layers of a cell (e.g., a tandem cell) as the former cell is easier and less expensive to make, thereby significantly reducing the manufacturing costs of the cell.

Without wishing to be bound by theory, it is believed that including (e.g., blending) both one or more low bandgap semiconducting polymers (e.g., the first polymer described above) and one or more relatively high bandgap semiconducting polymers (e.g., the second polymer described above) in a single photoactive layer and result in a layer with a relatively large thickness (e.g., at least about 200 nm) without sacrificing the charge transfer capability of the layer. Such a photoactive layer is easier and less expensive to make and therefore can significantly reduce the manufacturing costs of the photovoltaic cell.

Without wishing to be bound by theory, it is believed that including (e.g., blending) both one or more low bandgap semiconducting polymers (e.g., the first polymer described above) and one or more relatively high bandgap semiconducting polymers (e.g., the second polymer described above) in the photoactive layer could significantly improve the lifetime of a photovoltaic cell.

Other features and advantages of the invention will be apparent from the description, drawings, and claims.

### DESCRIPTION OF DRAWINGS

FIG. 1 is a cross-sectional view of an embodiment of a photovoltaic cell.

FIG. 2 is a cross-sectional view of an embodiment of a tandem photovoltaic cell.

FIG. 3 is a schematic of a system containing multiple photovoltaic cells electrically connected in series.

FIG. 4 is a schematic of a system containing multiple photovoltaic cells electrically connected in parallel.

Like reference symbols in the various drawings indicate like elements.

### DETAILED DESCRIPTION

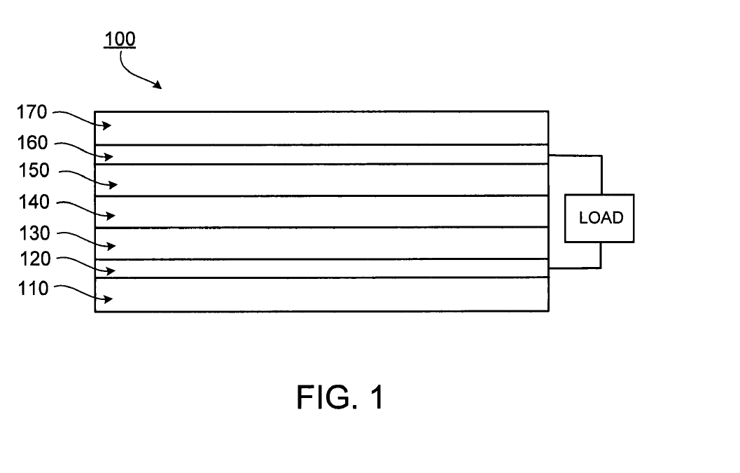

FIG. 1 shows a cross-sectional view of a photovoltaic cell 100 that includes a substrate 110, an electrode 120, an optional hole blocking layer 130, a photoactive layer 140 (containing an electron acceptor material and an electron donor material), a hole carrier layer 150, an electrode 160, and a substrate 170.

In general, one or both substrates 110 and 170 can be formed of a transparent material to transmit solar light. During use, when substrate 110 is formed of a transparent material, light impinges on the surface of substrate 110, and passes through substrate 110, electrode 120, and optional hole blocking layer 130. The light then interacts with photoactive layer 140, causing electrons to be transferred from the electron donor material (e.g., one or more conjugated polymers) to the electron acceptor material (e.g., a fullerene). The electron acceptor material then transmits the electrons through optional hole blocking layer 130 to electrode 120, and the electron donor material transfers holes through hole carrier layer 150 to electrode 160. Electrodes 120 and 160 are in electrical connection via an external load so that electrons pass from electrode 120, through the load, and to electrode 160.

In general, photoactive layer 140 can include an electron donor material (e.g., an organic electron donor material) and an electron acceptor material (e.g., an organic electron acceptor material). In some embodiments, the electron donor or acceptor material can include one or more polymers (e.g., homopolymers or copolymers). A polymer mentioned herein includes at least two identical or different monomer repeat units (e.g., at least 5 monomer repeat units, at least 10 monomer repeat units, at least 50 monomer repeat units, at least 100 monomer repeat units, or at least 500 monomer repeat units). A homopolymer mentioned herein refers to a polymer that includes only one type of monomer repeat units. A copolymer mentioned herein refers to a polymer that includes at least two (e.g., two, three, four or five) co-monomer repeat units with different chemical structures. The polymers can be conjugated semiconducting polymers and can be photovoltaically active.

In some embodiments, the electron donor material can include a first polymer and a second polymer different from the first polymer. In certain embodiments, the electron donor material can include more than two (e.g., three, four, or five) different polymers. Each polymer in the electron donor material can be either a homopolymer or a copolymer.

The first polymer in the electron donor material can be a copolymer and can include two or more (e.g., three, four, or five) different comonomer repeat units. For example, the first polymer can include a first comonomer repeat unit and a second comonomer repeat unit different from the first comonomer repeat unit.

The first comonomer repeat unit in the first polymer can include a silacyclopentadithiophene moiety of formula (1) or a cyclopentadithiophene moiety of formula (2):

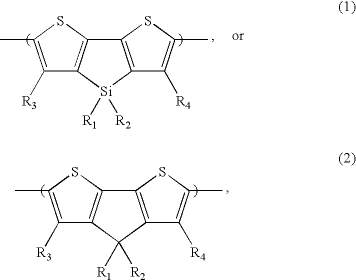

in which each of R₁, R₂, R₃, and R₄, independently, is H, C₁-C₂₀ alkyl (e.g., hexyl or 2-ethylhexyl), C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl.

An alkyl can be saturated or unsaturated and branched or straight chained. A C₁-C₂₀ alkyl contains 1 to 20 carbon atoms (e.g., one, two, three, four, five, six, seven, eight, nine, 10, 11, 12, 13, 14, 15, 16, 17, 18, 19, and 20 carbon atoms). Examples of alkyl moieties include —CH₃, —CH₂—CH═CH₂, and branched —C₃H₇. An alkoxy can be branched or straight chained and saturated or unsaturated. An C₁-C₂₀ alkoxy contains an oxygen radical and 1 to 20 carbon atoms (e.g., one, two, three, four, five, six, seven, eight, nine, 10, 11, 12, 13, 14, 15, 16, 17, 18, 19, and 20 carbon atoms). Examples of alkoxy moieties include —OCH₃ and —OCH═CH—CH₃. A cycloalkyl can be either saturated or unsaturated. A C₃-C₂₀ cycloalkyl contains 3 to 20 carbon atoms (e.g., three, four, five, six, seven, eight, nine, 10, 11, 12, 13, 14, 15, 16, 17, 18, 19, and 20 carbon atoms). Examples of cycloalkyl moieties include cyclohexyl and cyclohexen-3-yl. A heterocycloalkyl can also be either saturated or unsaturated. A C₁-C₂₀ heterocycloalkyl contains at least one ring heteroatom (e.g., O, N, and S) and 1 to 20 carbon atoms (e.g., one, two, three, four, five, six, seven, eight, nine, 10, 11, 12, 13, 14, 15, 16, 17, 18, 19, and 20 carbon atoms). Examples of heterocycloalkyl moieties include 4-tetrahydropyranyl and 4-pyranyl. An aryl can contain one or more aromatic rings. Examples of aryl moieties include phenyl, phenylene, naphthyl, naphthylene, pyrenyl, anthryl, and phenanthryl. A heteroaryl can contain one or more aromatic rings, at least one of which contains at least one ring heteroatom (e.g., O, N, and S). Examples of heteroaryl moieties include furyl, furylene, fluorenyl, pyrrolyl, thienyl, oxazolyl, imidazolyl, thiazolyl, pyridyl, pyrimidinyl, quinazolinyl, quinolyl, isoquinolyl, and indolyl.

Alkyl, alkoxy, cycloalkyl, heterocycloalkyl, aryl, and heteroaryl mentioned herein include both substituted and unsubstituted moieties, unless specified otherwise. Examples of substituents on cycloalkyl, heterocycloalkyl, aryl, and heteroaryl include C₁-C₂₀ alkyl, C₃-C₂₀ cycloalkyl, C₁-C₂₀ alkoxy, aryl, aryloxy, heteroaryl, heteroaryloxy, amino, C₁-C₁₀ alkylamino, C₁-C₂₀ dialkylamino, arylamino, diarylamino, hydroxyl, halogen, thio, C₁-C₁₀ alkylthio, arylthio, C₁-C₁₀ alkylsulfonyl, arylsulfonyl, cyano, nitro, acyl, acyloxy, carboxyl, and carboxylic ester. Examples of substituents on alkyl include all of the above-recited substituents except C₁-C₂₀ alkyl. Cycloalkyl, heterocycloalkyl, aryl, and heteroaryl also include fused groups.

The second comonomer repeat unit in the first polymer can include a benzothiadiazole moiety of formula (3):

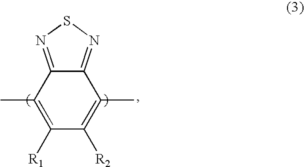

in which each of R₁ and R₂, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. For example, each of R₁ and R₂, independently, can be H.

The first polymer can further include a third comonomer repeat unit different from the first and second comonomer repeat units. For example, the third comonomer repeat unit can include a silacyclopentadithiophene moiety (e.g., a silacyclopentadithiophene moiety of formula (1) described above) or a cyclopentadithiophene moiety (e.g., a cyclopentadithiophene moiety of formula (2) described above).

Examples of the first polymer include

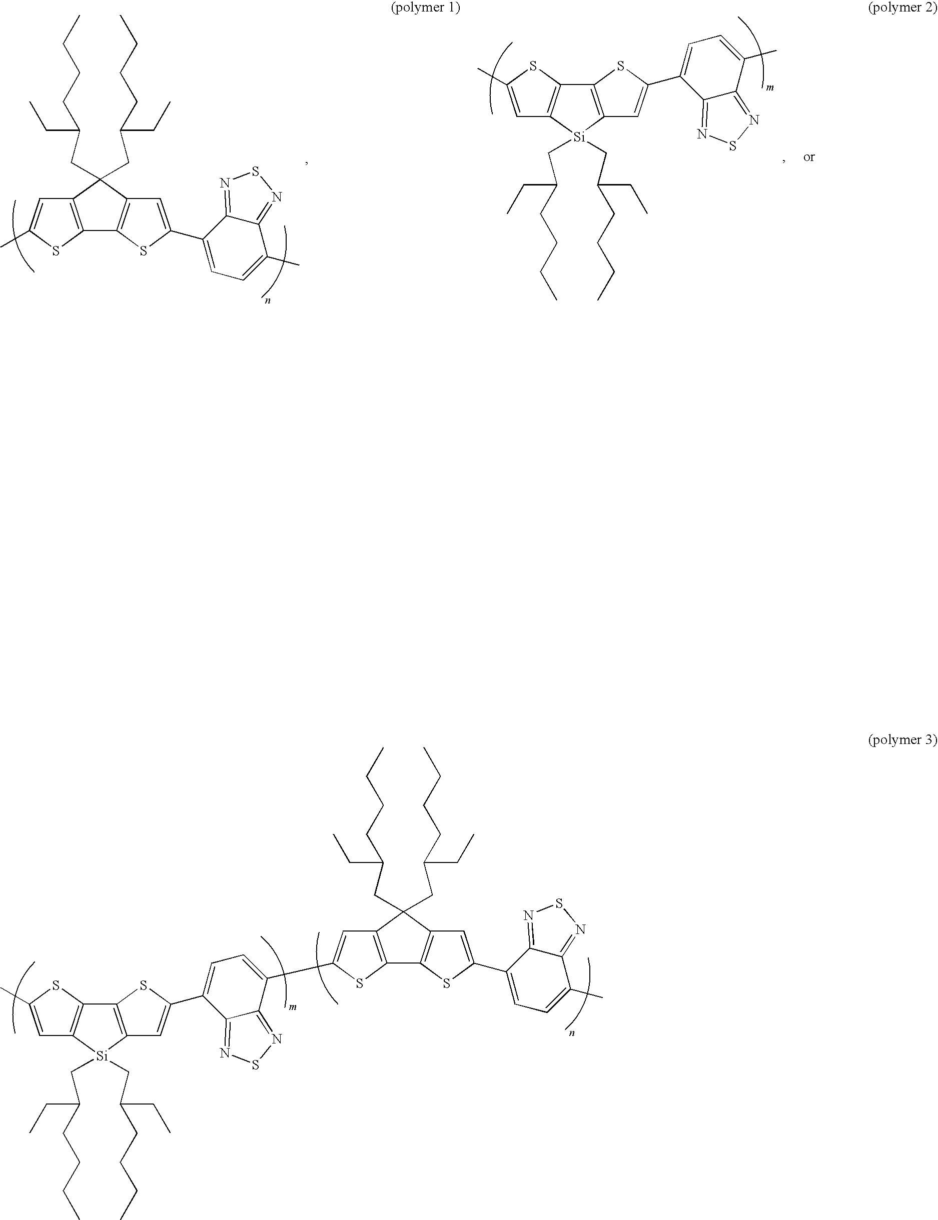

in which n is an integer from 1 to 1,000 and m is an integer from 1 to 1,000.

In some embodiments, the first polymer has a relatively low bandgap. The term “bandgap” mentioned herein refers to the energy difference between the top of the valence band (e.g., the HOMO level) and the bottom of the conduction band (e.g., the LUMO level) of a material. For example, the first polymer can have a bandgap of at most about 1.8 eV (at most about 1.7 eV, at most about 1.6 eV, at most about 1.5 eV, at most about 1.4 eV, or at most about 1.3 eV) or at least about 1.1 eV (e.g., at least about 1.2 eV, at least about 1.3 eV, at least about 1.4 eV, or at least about 1.5 eV). Preferably, the first polymer has a bandgap of from about 1.3 eV to about 1.6 eV (e.g., from about 1.4 eV to about 1.6 eV). For example, polymers 1-3 have a bandgap in the range of about 1.3 eV to about 1.4 eV.

In some embodiments, the second polymer in the electron donor material can be a homopolymer. The monomer repeat unit in the second polymer can contain a thiophene moiety, such as a thiophene moiety of formula (4):

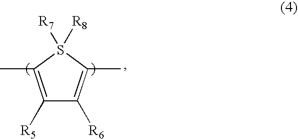

in which each of R₅, R₆, R₇, and R₈, independently, is H, C₁-C₂₀ alkyl (e.g., hexyl), C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. An example of the second polymer is poly(3-hexylthiophene).

In some embodiments, the second polymer has a relatively high bandgap. For example, the second polymer can have a bandgap of at least about 1.5 eV (at least about 1.6 eV, at least about 1.7 eV, at least about 1.8 eV, at least about 1.9 eV, or at least about 2.0 eV) or at most about 2.5 eV (e.g., at most about 2.4 eV, at most about 2.3 eV, at most about 2.2 eV, at most about 2.1 eV, or at most about 2.0 eV). For example, P3HT has a bandgap of about 1.9 eV. Preferably, the second polymer has a bandgap higher than that of the first polymer.

Other polymers that can be used as an electron donor material in photoactive layer 140 are described in, for example, commonly-owned co-pending U.S. Application Publication Nos. 2007-0014939, 2007-0158620, 2007-0017571, 2007-0020526, 2008-0087324, 2008-0121281, and 2010-0032018.

The first and second polymers can either be prepared by methods known in the art or purchased from commercial sources. For example, methods of preparing polymer containing a silacyclopentadithiophene moiety of formula (1) have been disclosed in commonly-owned co-pending U.S. Application Publication Nos. 2008-0087324 and 2010-0032018. As another example, methods of preparing polymers containing a cyclopentadithiophene moiety of formula (2) have been disclosed in commonly-owned co-pending U.S. Application Publication No. 2007-0014939. As another example, methods of preparing polymers containing benzothiadiazole moiety of formula (3) have been disclosed in commonly-owned co-pending U.S. Application Publication No. 2007-0158620. Polymers containing a thiophene moiety of formula (4) are generally commercially available or can be made by methods known in the art.

In general, the weight ratio of the first and second polymers can vary as desired. For example, the weight ratio of the first and second polymers can range from about 20:1 to about 1:20 (e.g., from about 10:1 to about 1:10, from about 5:1 to about 1:5, or from about 3:1 to about 1:3). Preferably, the weight ratio of the first and second polymers can be at least about 1:4, (e.g., at least about 1:3, at least about 1:2, or at least about 1:1).

Without wishing to be bound by theory, it is believed that including (e.g., blending) both one or more low bandgap semiconducting polymers (e.g., the first polymer described above) and one or more relatively high bandgap semiconducting polymers (e.g., the second polymer described above) in a single photoactive layer of a photovoltaic cell can significantly improve the power conversion efficiency of the photovoltaic cell (e.g., to at least about 4%). In some embodiments, when photoactive layer 140 includes two or more semiconducting polymers (such as the first and second polymers described above), photovoltaic cell 100 can have a power conversion efficiency of at least about 2.5% (e.g., at least about 3%, at least about 3.5%, at least about 4%, at least about 4.5%, or at least about 5%).

Further, without wishing to be bound by theory, it is believed that including (e.g., blending) both one or more low bandgap semiconducting polymers (e.g., the first polymer described above) and one or more relatively high bandgap semiconducting polymers (e.g., the second polymer described above) in a single photoactive layer of a photovoltaic cell provides an advantage over including these semiconducting polymers in two separate photoactive layers of a cell (e.g., a tandem cell) as the former cell is easier and less expensive to make, thereby significantly reducing the manufacturing costs of the cell.

In some embodiments, photoactive layer 140 can include two or more semiconducting polymers (e.g., one low bandgap polymer and one relatively high bandgap polymer) having complementary absorption spectra. For example, P3HT (i.e., an exemplary second polymer described above) has an absorption peak at the wavelength of about 500-550 nm. Polymer 1 (i.e., an exemplary first polymer described above) has an absorption peak at the wavelength of about 700-900 nm and has a minimum absorption at the wavelength of about 500-550 nm. Thus, including P3HT and polymer 1 in photoactive layer 140 can enhance light absorption within a broad solar light spectrum and improve the external quantum efficiency of photovoltaic cell 100, and consequently improve the power conversion efficiency of the photovoltaic cell.

In some embodiments, the first polymer, the second polymer, and the electron acceptor material can have first HOMO and LUMO levels, second HOMO and LUMO levels, and third HOMO and LUMO levels, respectively. Preferably, the first HOMO level falls between the HOMO levels of the second polymer and the electron acceptor material. In such embodiments, photo-induced positive charges (e.g., holes) generated from the first polymer can be transferred to the second polymer. As such, both the first and second polymers contribute to charge generation and transfer, thereby improving the external quantum efficiency and the power conversion efficiency of photovoltaic cell 100. In addition, as the second polymer is generally a superior charger carrier, it can facilitate transfer of positive charges generated from the first polymer to a corresponding electrode in the event that the first polymer has a relatively poor charge transfer capability.

On the other hand, there is no significant transfer of negative charges (e.g., electrons) between the first and second polymers. Thus, it is not critical for the first LUMO level to fall between the second and third LUMO levels. However, in some embodiments, it is preferable for the first LUMO level to fall between the second and third LUMO levels.

In some embodiments, photoactive layer 140 can include a semiconducting polymer (e.g., a low bandgap polymer such as the first polymer) having a HOMO level and a LUMO level that respectively fall between the HOMO levels and LUMO levels of another semiconductor polymer (e.g., a relatively high bandgap polymer such as the second polymer) and the electron acceptor material (e.g., a fullerene such as C60-PCBM). For example, polymer 1 has a HOMO level of about −5.3 eV that falls between the HOMO levels of P3HT (i.e., about −5.1 eV) and C60-PCBM (i.e., about −6 eV) and a LUMO level of about −3.6 eV that falls between the LUMO levels of P3HT (i.e., about 2.9 eV) and C60-PCBM (i.e., about −4.3 eV). Thus, photo-induced electrons from polymer 1 can be transferred to C60-PCBM (and subsequently to a neighboring electrode) and photo-induced holes from polymer 1 can be transferred to P3HT (and subsequently to a neighboring electrode). In other words, in addition to electron donor P3HT, electron donor polymer 1 can also contribute to charge generation and transfer, thereby improving the external quantum efficiency and the power conversion efficiency of photovoltaic cell 100.

It is known in the art that increasing the thickness of the photoactive layer in a photovoltaic cell would generally make it more difficult for photo-induced charge carriers generated in this layer to be transferred to a neighboring layer and eventually to the corresponding electrode, thereby reducing the charge transfer capability of the photoactive layer. However, it is found unexpectedly that including (e.g., blending) both one or more low bandgap semiconducting polymers (e.g., the first polymer described above) and one or more relatively high bandgap semiconducting polymers (e.g., the second polymer described above) in a single photoactive layer can result in a layer with a relatively large thickness (e.g., at least about 150 nm) without sacrificing the charge transfer capability of the layer. Such a photoactive layer is easier and less expensive to make and therefore can significantly reduce the manufacturing costs of the photovoltaic cell. In some embodiments, such a photoactive layer can have a thickness of at least about 100 nm (e.g., at least about 150 nm, at least about 200 nm, at least about 300 nm, or at least about 500 nm).

Further, without wishing to be bound by theory, it is found unexpectedly that including (e.g., blending) both one or more low bandgap semiconducting polymers (e.g., the first polymer described above) and one or more relatively high bandgap semiconducting polymers (e.g., the second polymer described above) in a single photoactive layer can significantly improve the lifetime of a photovoltaic cell.

In some embodiments, the electron acceptor material in photoactive layer 140 can include a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof. For example, the electron acceptor material can include fullerenes (e.g., substituted fullerenes).

In some embodiments, photoactive layer 140 can include one or more unsubstituted fullerenes and/or one or more substituted fullerenes as the electron acceptor material. Examples of unsubstituted fullerenes include C₆₀, C₇₀, C₇₆, C₇₈, C₈₂, C₈₄, and C₉₂. Examples of substituted fullerenes include PCBMs (e.g., C60-PCBM, C70-PCBM, Bis-C60-PCBM, or Bis-C70-PCBM) or fullerenes substituted with C₁-C₂₀ alkoxy optionally further substituted with C₁-C₂₀ alkoxy and/or halo (e.g., (OCH₂CH₂)₂OCH₃ or OCH₂CF₂OCF₂CF₂OCF₃). Without wishing to be bound by theory, it is believed that fullerenes substituted with long-chain alkoxy groups (e.g., oligomeric ethylene oxides) or fluorinated alkoxy groups have improved solubility in organic solvents and can form a photoactive layer with improved morphology. Other materials that can be used as an electron acceptor material in photoactive layer 140 are described in, for example, commonly-owned co-pending U.S. Application Publication Nos. 2007-0014939, 2007-0158620, 2007-0017571, 2007-0020526, 2008-0087324, 2008-0121281, and 2010-0032018. In certain embodiments, a combination of electron acceptors (e.g., two different fullerenes) can be used in photoactive layer 140. Such embodiments have been described in, for example, commonly-owned co-pending U.S. Application Publication No. 2007-0062577.

In general, the weight ratio between the electron donor material and the electron acceptor material can vary as desired. In some embodiments, the weight ratio of the electron donor material and the electron acceptor material ranges from about 1:1 to about 1:3 (preferably about 1:1).

It is known in the art that blending two or more semiconducting polymers (e.g., blending an electron donor polymer with an electron acceptor polymer) could lead to large phase separation with domain size in several micrometers, which could significantly reduce the charge transfer capability of the photoactive layer thus formed and consequently lower the power conversion efficiency of the photovoltaic cell. Unexpectedly, blending the first and second polymers described above does not show significant phase separation (e.g., having a domain size larger than 500 nm) between these two polymers and therefore minimizes the efficiency loss caused by phase separation between these two polymers.

Photoactive layer 140 is generally formed by mixing the electron donor material (e.g., the first and second polymers described above) and the electron acceptor material (e.g., a substituted fullerene) with a suitable solvent (e.g., an organic solvent) to form a solution or a dispersion, coating the solution or dispersion on layer 130, and drying the coated solution or dispersion.

In general, after photoactive layer 140 is formed (e.g., after the entire photovoltaic cell 100 is formed), it is desirable to anneal this layer (e.g., by heating) at a suitable temperature for a suitable period of time. The annealing temperature can be at least about 70° C. (e.g., at least about 80° C., at least about 100° C., at least about 120° C., or at least about 140° C.) or at most about 200° C. (e.g., at most about 180° C., at most about 160° C., at most about 140° C., or at most about 120° C.). The annealing time can be at least about 30 seconds (e.g., at least about 1 minute, at least about 3 minute, at least about 5 minute, or at least about 7 minute) or at most about 15 minutes (e.g., at most about 13 minutes, at most about 11 minutes, at most about 9 minutes, or at most about 7 minutes). Without wishing to be bound by theory, it is believed that non-annealed photoactive layer would have a lowered short circuit current density, a lowered fill factor, and an elevated serial resistance. However, annealing photoactive layer 140 could significantly improve the short circuit current density and therefore increase the power conversion efficiency of photovoltaic cell 100.

Turning to other components of photovoltaic cell 100, substrate 110 is generally formed of a transparent material. As referred to herein, a transparent material is a material which, at the thickness used in a photovoltaic cell 100, transmits at least about 60% (e.g., at least about 70%, at least about 75%, at least about 80%, at least about 85%) of incident light at a wavelength or a range of wavelengths (e.g., from about 350 nm to about 1,000 nm) used during operation of the photovoltaic cell. Exemplary materials from which substrate 110 can be formed include polyethylene terephthalates, polyimides, polyethylene naphthalates, polymeric hydrocarbons, cellulosic polymers, polycarbonates, polyamides, polyethers, and polyether ketones. In certain embodiments, the polymer can be a fluorinated polymer. In some embodiments, combinations of polymeric materials are used. In certain embodiments, different regions of substrate 110 can be formed of different materials.

In general, substrate 110 can be flexible, semi-rigid or rigid (e.g., glass). In some embodiments, substrate 110 has a flexural modulus of less than about 5,000 megaPascals (e.g., less than about 1,000 megaPascals or less than about 5,00 megaPascals). In certain embodiments, different regions of substrate 110 can be flexible, semi-rigid, or inflexible (e.g., one or more regions flexible and one or more different regions semi-rigid, one or more regions flexible and one or more different regions inflexible).

Typically, substrate 110 is at least about one micron (e.g., at least about five microns, at least about 10 microns) thick and/or at most about 1,000 microns (e.g., at most about 500 microns thick, at most about 300 microns thick, at most about 200 microns thick, at most about 100 microns, at most about 50 microns) thick.

Generally, substrate 110 can be colored or non-colored. In some embodiments, one or more portions of substrate 110 is/are colored while one or more different portions of substrate 110 is/are non-colored.

Substrate 110 can have one planar surface (e.g., the surface on which light impinges), two planar surfaces (e.g., the surface on which light impinges and the opposite surface), or no planar surfaces. A non-planar surface of substrate 110 can, for example, be curved or stepped. In some embodiments, a non-planar surface of substrate 110 is patterned (e.g., having patterned steps to form a Fresnel lens, a lenticular lens or a lenticular prism).

Electrode 120 is generally formed of an electrically conductive material. Exemplary electrically conductive materials include electrically conductive metals, electrically conductive alloys, electrically conductive polymers, and electrically conductive metal oxides. Exemplary electrically conductive metals include gold, silver, copper, aluminum, nickel, palladium, platinum, and titanium. Exemplary electrically conductive alloys include stainless steel (e.g., 332 stainless steel, 316 stainless steel), alloys of gold, alloys of silver, alloys of copper, alloys of aluminum, alloys of nickel, alloys of palladium, alloys of platinum and alloys of titanium. Exemplary electrically conducting polymers include polythiophenes (e.g., doped poly(3,4-ethylenedioxythiophene) (doped PEDOT)), polyanilines (e.g., doped polyanilines), polypyrroles (e.g., doped polypyrroles). Exemplary electrically conducting metal oxides include indium tin oxide, fluorinated tin oxide, tin oxide and zinc oxide. In some embodiments, combinations of electrically conductive materials are used.

In some embodiments, electrode 120 can include a mesh electrode. Examples of mesh electrodes are described in, for example, commonly-owned co-pending U.S. Patent Application Publication Nos. 2004-0187911 and 2006-0090791.

Optionally, photovoltaic cell 100 can include a hole blocking layer 130. The hole blocking layer is generally formed of a material that, at the thickness used in photovoltaic cell 100, transports electrons to electrode 120 and substantially blocks the transport of holes to electrode 120. Examples of materials from which the hole blocking layer can be formed include LiF, metal oxides (e.g., zinc oxide, titanium oxide), and amines (e.g., primary, secondary, or tertiary amines, or polymer containing amino groups). Examples of amines suitable for use in a hole blocking layer have been described in, for example, commonly-owned co-pending U.S. Patent Application Publication No. 2008-0264488.

Without wishing to be bound by theory, it is believed that when photovoltaic cell 100 includes a hole blocking layer made of amines, the hole blocking layer can facilitate the formation of ohmic contact between photoactive layer 140 and electrode 120 without being exposed to UV light, thereby reducing damage to photovoltaic cell 100 resulted from UV exposure.

In general, the thickness of hole blocking layer 130 (i.e., the distance between the surface of hole blocking layer 130 in contact with photoactive layer 140 and the surface of electrode 120 in contact with hole blocking layer 130) can be varied as desired. Typically, hole blocking layer 130 is at least 0.02 micron (e.g., at least about 0.03 micron, at least about 0.04 micron, at least about 0.05 micron) thick and/or at most about 0.5 micron (e.g., at most about 0.4 micron, at most about 0.3 micron, at most about 0.2 micron, at most about 0.1 micron) thick.

Hole carrier layer 150 is generally formed of a material that, at the thickness used in photovoltaic cell 100, transports holes to electrode 160 and substantially blocks the transport of electrons to electrode 160. Examples of materials from which layer 130 can be formed include polythiophenes (e.g., PEDOT), polyanilines, polycarbazoles, polyvinylcarbazoles, polyphenylenes, polyphenylvinylenes, polysilanes, polythienylenevinylenes, polyisothianaphthanenes, and copolymers thereof. In some embodiments, hole carrier layer 150 can include a dopant used in combination with a semiconductive polymer. Examples of dopants include poly(styrene-sulfonate)s, polymeric sulfonic acids, and fluorinated polymers (e.g., fluorinated ion exchange polymers).

In some embodiments, the materials that can be used to form hole carrier layer 150 include metal oxides, such as titanium oxides, zinc oxides, tungsten oxides, molybdenum oxides, copper oxides, strontium copper oxides, or strontium titanium oxides. The metal oxides can be either undoped or doped with a dopant. Examples of dopants for metal oxides includes salts or acids of fluoride, chloride, bromide, and iodide.

In some embodiments, the materials that can be used to form hole carrier layer 150 include carbon allotropes (e.g., carbon nanotubes). The carbon allotropes can be embedded in a polymer binder.

In some embodiments, the hole carrier materials can be in the form of nanoparticles. The nanoparticles can have any suitable shape, such as a spherical, cylindrical, or rod-like shape.

In some embodiments, hole carrier layer 150 can include combinations of hole carrier materials described above.

In general, the thickness of hole carrier layer 150 (i.e., the distance between the surface of hole carrier layer 150 in contact with photoactive layer 140 and the surface of electrode 160 in contact with hole carrier layer 150) can be varied as desired. Typically, the thickness of hole carrier layer 150 is at least 0.01 micron (e.g., at least about 0.05 micron, at least about 0.1 micron, at least about 0.2 micron, at least about 0.3 micron, or at least about 0.5 micron) and/or at most about five microns (e.g., at most about three microns, at most about two microns, or at most about one micron). In some embodiments, the thickness of hole carrier layer 150 is from about 0.01 micron to about 0.5 micron.

Electrode 160 is generally formed of an electrically conductive material, such as one or more of the electrically conductive materials described above with respect to electrode 120. In some embodiments, electrode 160 is formed of a combination of electrically conductive materials. In certain embodiments, electrode 160 can be formed of a mesh electrode.

Substrate 170 can be identical to or different from substrate 110. In some embodiments, substrate 170 can be formed of one or more suitable polymers, such as the polymers used in substrate 110 described above.

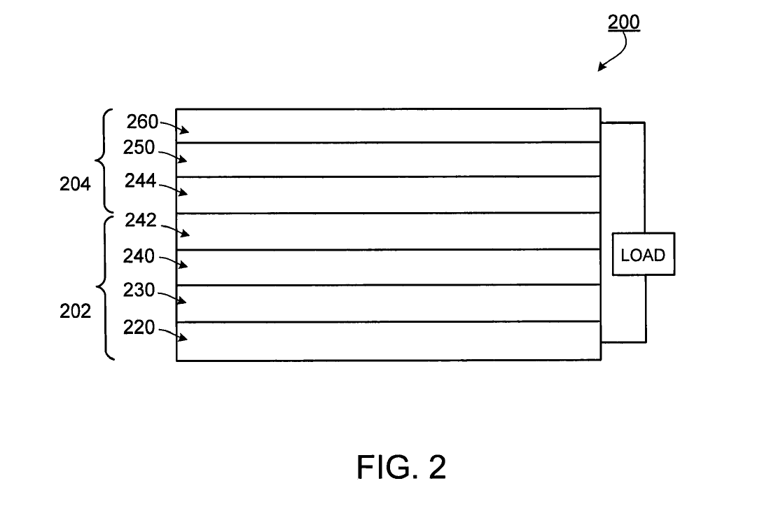

In some embodiments, the semiconducting polymers described above (such as the first and second polymers) can be used as an electron donor material in a system in which two photovoltaic cells share a common electrode. Such a system is also known as tandem photovoltaic cell. FIG. 2 shows a tandem photovoltaic cell 200 having two semi-cells 202 and 204. Semi-cell 202 includes an electrode 220, an optional hole blocking layer 230, a first photoactive layer 240, and a recombination layer 242 (also serving as a common electrode). Semi-cell 204 includes recombination layer 242, a second photoactive layer 244, a hole carrier layer 250, and an electrode 260. An external load is connected to photovoltaic cell 200 via electrodes 220 and 260.

Depending on the production process and the desired device architecture, the current flow in a semi-cell can be reversed by changing the electron/hole conductivity of a certain layer (e.g., changing hole blocking layer 230 to a hole carrier layer). By doing so, a tandem cell can be designed such that the semi-cells in the tandem cells can be electrically interconnected either in series or in parallel.

A recombination layer refers to a layer in a tandem cell where the electrons generated from a first semi-cell recombine with the holes generated from a second semi-cell. Recombination layer 242 typically includes a p-type semiconductor material and an n-type semiconductor material. In general, n-type semiconductor materials selectively transport electrons and p-type semiconductor materials selectively transport holes. As a result, electrons generated from the first semi-cell recombine with holes generated from the second semi-cell at the interface of the n-type and p-type semiconductor materials.

In some embodiments, the p-type semiconductor material includes a polymer and/or a metal oxide. Examples of p-type semiconductor polymers include polythiophenes (e.g., poly(3,4-ethylene dioxythiophene)), polyanilines, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, and copolymers thereof. The metal oxide can be an intrinsic p-type semiconductor (e.g., copper oxides, strontium copper oxides, or strontium titanium oxides) or a metal oxide that forms a p-type semiconductor after doping with a dopant (e.g., p-doped zinc oxides or p-doped titanium oxides). Examples of dopants includes salts or acids of fluoride, chloride, bromide, and iodide. In some embodiments, the metal oxide can be used in the form of nanoparticles.

In some embodiments, the n-type semiconductor material (either an intrinsic or doped n-type semiconductor material) includes a metal oxide, such as titanium oxides, zinc oxides, tungsten oxides, molybdenum oxides, and combinations thereof. The metal oxide can be used in the form of nanoparticles. In other embodiments, the n-type semiconductor material includes a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

In some embodiments, the p-type and n-type semiconductor materials are blended into one layer. In certain embodiments, recombination layer 242 includes two layers, one layer including the p-type semiconductor material and the other layer including the n-type semiconductor material. In such embodiments, recombination layer 242 can also include three layers, in which the first layer includes the p-type semiconductor material, the second layer includes the n-type semiconductor material, and the third layer containing mixed n-type and p-type semiconductor materials is between the first and second layers.

In some embodiments, recombination layer 242 includes at least about 30 wt % (e.g., at least about 40 wt % or at least about 50 wt %) and/or at most about 70 wt % (e.g., at most about 60 wt % or at most about 50 wt %) of the p-type semiconductor material. In some embodiments, recombination layer 242 includes at least about 30 wt % (e.g., at least about 40 wt % or at least about 50 wt %) and/or at most about 70 wt % (e.g., at most about 60 wt % or at most about 50 wt %) of the n-type semiconductor material.

Recombination layer 242 generally has a sufficient thickness so that the layers underneath are protected from any solvent applied onto recombination layer 242. In some embodiments, recombination layer 242 can have a thickness at least about 10 nm (e.g., at least about 20 nm, at least about 50 nm, or at least about 100 nm) and/or at most about 500 nm (e.g., at most about 200 nm, at most about 150 nm, or at most about 100 nm).

In general, recombination layer 242 is substantially transparent. For example, at the thickness used in a tandem photovoltaic cell 200, recombination layer 242 can transmit at least about 70% (e.g., at least about 75%, at least about 80%, at least about 85%, or at least about 90%) of incident light at a wavelength or a range of wavelengths (e.g., from about 350 nm to about 1,000 nm) used during operation of the photovoltaic cell.

Recombination layer 242 generally has a sufficiently low surface resistance. In some embodiments, recombination layer 242 has a surface resistance of at most about 1×10⁶ ohm/square (e.g., at most about 5×10⁵ ohm/square, at most about 2×10⁵ ohm/square, or at most about 1×10⁵ ohm/square).

Without wishing to be bound by theory, it is believed that recombination layer 242 can be considered as a common electrode between two semi-cells (e.g., one including electrode 220, hole blocking layer 230, photoactive layer 240, and recombination layer 242, and the other including recombination layer 242, photoactive layer 244, hole carrier layer 250, and electrode 260) in photovoltaic cells 200. In some embodiments, recombination layer 242 can include an electrically conductive grid (e.g., mesh) material, such as those described above. An electrically conductive grid material can provide a selective contact of the same polarity (either p-type or n-type) to the semi-cells and provide a highly conductive but transparent layer to transport electrons to a load.

In some embodiments, recombination layer 242 can be prepared by applying a blend of an n-type semiconductor material and a p-type semiconductor material on a photoactive layer. For example, an n-type semiconductor and a p-type semiconductor can be first dispersed or dissolved in a solvent together to form a dispersion or solution, which can then be coated on a photoactive layer to form a recombination layer.

In some embodiments, a two-layer recombination layer can be prepared by applying a layer of an n-type semiconductor material and a layer of a p-type semiconductor material separately. For example, when titanium oxide nanoparticles are used as an n-type semiconductor material, a layer of titanium oxide nanoparticles can be formed by (1) dispersing a precursor (e.g., a titanium salt) in a solvent (e.g., an organic solvent such as an anhydrous alcohol) to form a dispersion, (2) coating the dispersion on a photoactive layer, (3) hydrolyzing the dispersion to form a titanium oxide layer, and (4) drying the titanium oxide layer. As another example, when a polymer (e.g., PEDOT) is used a p-type semiconductor, a polymer layer can be formed by first dissolving the polymer in a solvent (e.g., an organic solvent such as an anhydrous alcohol) to form a solution and then coating the solution on a photoactive layer.

Other components in tandem cell 200 can be formed of the same materials, or have the same characteristics, as those in photovoltaic cell 100 described above.

Examples of tandem photovoltaic cells have been described in, for example, commonly-owned co-pending U.S. Application Publication Nos. 2007-0181179 and 2007-0246094.

In some embodiments, the semi-cells in a tandem cell are electrically interconnected in series. When connected in series, in general, the layers can be in the order shown in FIG. 2. In certain embodiments, the semi-cells in a tandem cell are electrically interconnected in parallel. When interconnected in parallel, a tandem cell having two semi-cells can include the following layers: a first electrode, a first hole blocking layer, a first photoactive layer, a first hole carrier layer (which can serve as an electrode), a second hole carrier layer (which can serve as an electrode), a second photoactive layer, a second hole blocking layer, and a second electrode. In such embodiments, the first and second hole carrier layers together can be a recombination layer, which can include either two separate layers or can be one single layer. In case the conductivity of the first and second hole carrier layers is not sufficient, an additional layer (e.g., an electrically conductive mesh layer) providing the required conductivity may be inserted.

In some embodiments, a tandem cell can include more than two semi-cells (e.g., three, four, five, six, seven, eight, nine, ten, or more semi-cells). In certain embodiments, some semi-cells can be electrically interconnected in series and some semi-cells can be electrically interconnected in parallel.

In general, the methods of preparing each layer in photovoltaic cells described in FIGS. 1 and 2 can vary as desired. In some embodiments, a layer can be prepared by a liquid-based coating process. In certain embodiments, a layer can be prepared via a gas phase-based coating process, such as chemical or physical vapor deposition processes.

The term “liquid-based coating process” mentioned herein refers to a process that uses a liquid-based coating composition. Examples of the liquid-based coating composition include solutions, dispersions, or suspensions. The liquid-based coating process can be carried out by using at least one of the following processes: solution coating, ink jet printing, spin coating, dip coating, knife coating, bar coating, spray coating, roller coating, slot coating, gravure coating, flexographic printing, or screen printing. Examples of liquid-based coating processes have been described in, for example, commonly-owned co-pending U.S. Application Publication No. 2008-0006324.

In some embodiments, when a layer includes inorganic semiconductor nanoparticles, the liquid-based coating process can be carried out by (1) mixing the nanoparticles with a solvent (e.g., an aqueous solvent or an organic solvent such as an anhydrous alcohol) to form a dispersion, (2) coating the dispersion onto a substrate, and (3) drying the coated dispersion. In certain embodiments, a liquid-based coating process for preparing a layer containing inorganic metal oxide nanoparticles can be carried out by (1) dispersing a precursor (e.g., a titanium salt) in a suitable solvent (e.g., an anhydrous alcohol) to form a dispersion, (2) coating the dispersion on a substrate, (3) hydrolyzing the dispersion to form an inorganic semiconductor nanoparticles layer (e.g., a titanium oxide nanoparticles layer), and (4) drying the inorganic semiconductor material layer. In certain embodiments, the liquid-based coating process can be carried out by a sol-gel process (e.g., by forming metal oxide nanoparticles as a sol-gel in a dispersion before coating the dispersion on a substrate).

In general, the liquid-based coating process used to prepare a layer containing an organic semiconductor material can be the same as or different from that used to prepare a layer containing an inorganic semiconductor material. In some embodiments, when a layer includes an organic semiconductor material, the liquid-based coating process can be carried out by mixing the organic semiconductor material with a solvent (e.g., an organic solvent) to form a solution or a dispersion, coating the solution or dispersion on a substrate, and drying the coated solution or dispersion.

In some embodiments, the photovoltaic cells described in FIGS. 1 and 2 can be prepared in a continuous manufacturing process, such as a roll-to-roll process, thereby significantly reducing the manufacturing cost. Examples of roll-to-roll processes have been described in, for example, commonly-owned co-pending U.S. Application Publication No. 2005-0263179.

While certain embodiments have been disclosed, other embodiments are also possible.

In some embodiments, photovoltaic cell 100 includes a cathode as a bottom electrode and an anode as a top electrode. In some embodiments, photovoltaic cell 100 can also include an anode as a bottom electrode and a cathode as a top electrode.

In some embodiments, photovoltaic cell 100 can include the layers shown in FIG. 1 in a reverse order. In other words, photovoltaic cell 100 can include these layers from the bottom to the top in the following sequence: a substrate 170, an electrode 160, a hole carrier layer 150, a photoactive layer 140, an optional hole blocking layer 130, an electrode 120, and a substrate 110.

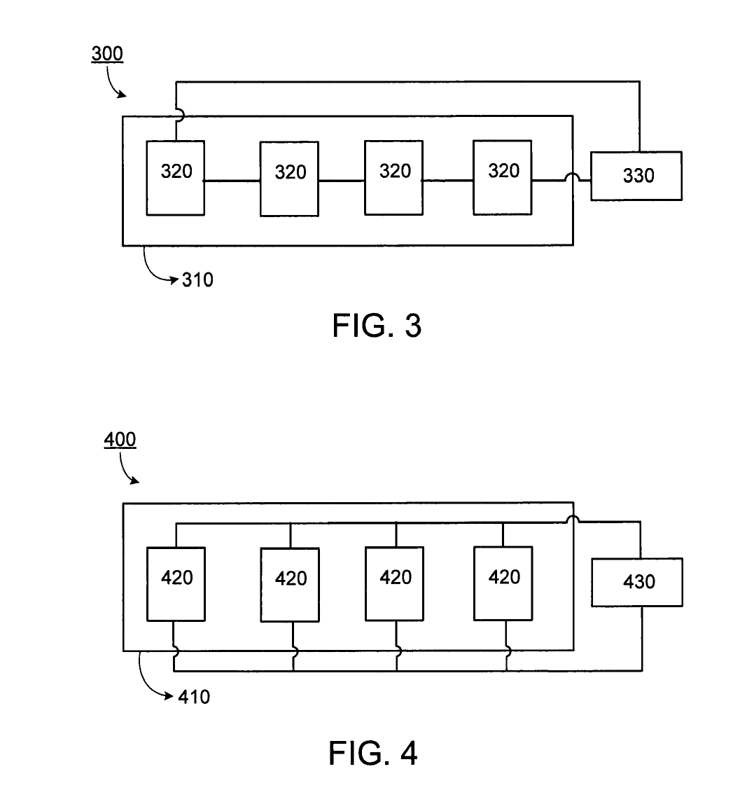

In some embodiments, multiple photovoltaic cells can be electrically connected to form a photovoltaic system. As an example, FIG. 3 is a schematic of a photovoltaic system 300 having a module 310 containing photovoltaic cells 320. Cells 320 are electrically connected in series, and system 300 is electrically connected to a load 330. As another example, FIG. 4 is a schematic of a photovoltaic system 400 having a module 410 that contains photovoltaic cells 420. Cells 420 are electrically connected in parallel, and system 400 is electrically connected to a load 430. In some embodiments, some (e.g., all) of the photovoltaic cells in a photovoltaic system can have one or more common substrates. In certain embodiments, some photovoltaic cells in a photovoltaic system are electrically connected in series, and some of the photovoltaic cells in the photovoltaic system are electrically connected in parallel.

While organic photovoltaic cells have been described, other photovoltaic cells can also be integrated with one or more of the semiconducting polymers described herein. Examples of such photovoltaic cells include dye sensitized photovoltaic cells and inorganic photoactive cells with an photoactive material formed of amorphous silicon, cadmium selenide, cadmium telluride, copper indium selenide, and copper indium gallium selenide. In some embodiments, a hybrid photovoltaic cell can be integrated with one or more of the semiconducting polymers described herein.

While photovoltaic cells have been described above, in some embodiments, the polymers described herein can be used in other devices and systems. For example, the polymers can be used in suitable organic semiconductive devices, such as field effect transistors, photodetectors (e.g., IR detectors), photovoltaic detectors, imaging devices (e.g., RGB imaging devices for cameras or medical imaging systems), light emitting diodes (LEDs) (e.g., organic LEDs (OLEDs) or IR or near IR LEDs), lasing devices, conversion layers (e.g., layers that convert visible emission into IR emission), amplifiers and emitters for telecommunication (e.g., dopants for fibers), storage elements (e.g., holographic storage elements), and electrochromic devices (e.g., electrochromic displays).

All publications, patent applications, patents, and other references mentioned herein are incorporated by reference herein in their entirety.

The following examples are illustrative and not intended to be limiting.

### EXAMPLE 1

### Fabrication of Photovoltaic Cells Containing Two Semiconducting Polymers

Poly(3,4-ethylenedioxy thiophene)/poly(styrene sulfonicacid) (PEDOT:PSS) (Baytron PH) was purchased from H.C. Starck. P3HT (4002E) was purchased from Rieke. Polymer 1 was prepared by Konarka Technologies, Inc. following the procedures described in U.S. Application Publication No. 2007-0014939. C60-PCBM was purchased from SolenneBV.

Photovoltaic devices were fabricated as follows: A 100 nm hole carrier layer containing PEDOT:PSS was first coated on indium tin oxide (ITO) covered glass substrates (Merck) by doctor blading. P3HT, polymer 1 (having a number-average molecular weight of 35,000 g/mol and a weight-average molecular weight of 47,000 g/mol), and C60-PCBM were dissolved in o-dicholorbenzene in different weight ratios. The solution thus formed was deposited via doctor-blading on top of the PEDOT:PSS layer to form a photoactive layer. A LiF/Al (0.6 nm/80 nm) metal electrode was then thermally deposited onto the photoactive layer to form a photovoltaic cell.

Following the procedures above, three photovoltaic cells containing P3HT, polymer 1 and C60-PCBM in the following weight ratios were prepared: (1) 95:5:100, (2) 9:1:10, and (3) 8:2:10, respectively. A fourth photovoltaic cell (i.e., cell (4)) without polymer 1 was also prepared and used as a control.

The current-voltage characteristics of photovoltaic cells (1)-(4) were measured using a Keithley 2400 SMU while the solar cells were illuminated under AM1.5G irradiation on an Oriel Xenon solar simulator (100 mW cm⁻²). The results showed that cells (1)-(4) exhibited power conversion efficiencies of 2.48%, 2.38%, 2.86%, and 2.6%, respectively. The results indicated that a photovoltaic cell containing 20% polymer 1 in the electron donor material in the photoactive layer (i.e., cell (3)) exhibited a higher power conversion efficiency than that of a photovoltaic cell containing P3HT alone as the electron donor material (i.e., cell (4)).

### EXAMPLE 2

### Fabrication of Photovoltaic Cells Having Different Photoactive Layer Thickness

P3HT and PEDOT:PSS were purchased from the same commercial sources as those described in Example 1. Polymers 2 and 3 were prepared by Konarka Technologies, Inc. following the procedures described in U.S. Application Publications No. 2008-0087324 and 2010-0032018, respectively. C70-PCBM and Bis-C60-PCBM were purchased from SolenneBV.

For device preparation, all photoactive materials were mixed in the desired weight ratios and dissolved in o-dichlorobenzene. Devices were prepared in the following way:

Photovoltaic cells were prepared as follows: An ITO coated glass substrate was cleaned by sonicating in isopropanol. A thin electron injection layer containing polyethyleneimine and glycerol propoxylate triglycidyl ether was then formed by blade coating a solution on top of the ITO. An o-dichlorobenzene solution containing one or two semiconductor polymers as an electron donor material and a substituted fullerene as an electron acceptor material was blade coated onto the hole blocking layer and then dried to form a photoactive layer. A solution containing PEDOT:PSS was blade coated on top of the photoactive layer to form a hole carrier layer. A silver electrode was then thermally deposited onto the hole carrier layer to form a photovoltaic cell.

Four photovoltaic cells were prepared following the procedures above. Photovoltaic cell (1) included a photoactive layer containing polymer 2 and C70-PCBM in a weight ratio of 1:2 and having a thickness of less than 100 nm. Photovoltaic cell (2) included a photoactive layer containing polymer 2 and C70-PCBM in a weight ratio of 1:2 and having a thickness of between 100 nm and 200 nm. Photovoltaic cell (3) included a photoactive layer containing P3HT, polymer 2, and C70-PCBM in a weight ratio of 5.6:1:6.7 and having a thickness of between 150 nm and 200 nm. Photovoltaic cell (4) included a photoactive layer containing P3HT, polymer 3, and Bis-C60-PCBM in a weight ratio of 5.6:1:6.7 and having a thickness of about 200 nm.

The current-voltage characteristics of photovoltaic cells were measured using a Keithley 2400 SMU while the solar cells were exposed to simulated sun-light delivered by an Steuernagel Solar Simulator (70-80 mW cm⁻²). The results show that photovoltaic cells (1)-(4) exhibited power conversion efficiencies of about 4.5%, 3.6%, 4.2%, and 4.6%, respectively. Without wishing to be bound by theory, it is believed that cell (2) exhibited a lower power conversion efficiency than that of cell (1) due to its larger thickness of the photoactive layer, which would decrease its capability to transfer charge carriers (i.e., electrons or holes) to the neighbouring hole block or carrier layer. Further, without wishing to be bound by theory, it is believed that cell (3) exhibited a higher power conversion efficiency than that of cell (2) due to the presence of a combination of a low bandgap semiconducting polymer (i.e., polymer 2) and a relatively high bandgap semiconducting polymer (i.e., P3HT), which could improve the charge carrier capability of the photoactive layer and even though cell (3) had a photoactive layer with a thickness similar to that of cell (2). In addition, the results showed that replacing polymer 2 and C70-PCBM used in cell (3) with polymer 3 and Bis-C60-PCBM used in cell (4), respectively, could result in a photovoltaic cell with a higher efficiency.

### EXAMPLE 3

### Lifetime of Photovoltaic Cells Containing Different Photoactive Layers

Two photovoltaic cells were prepared following the procedures described in Example 2 above. Photovoltaic cell (1) included a photoactive layer containing P3HT, polymer 3, and Bis-C60-PCBM in a weight ratio of 5.6:1:6.7. Photovoltaic cell (2) included a photoactive layer containing P3HT and Bis-C60-PCBM in a weight ratio of 1:1.

The power conversion efficiencies of cells (1) and (2) were measured following the procedures described in Example 2 after these two cells were heated at 65° C. under 85% humidity after a certain period of time (i.e., an accelerated experiment for measuring the lifetime of a photovoltaic cell). The results showed that cell (2) lost 20% of its efficiency after about 190 hours of heat treatment, while cell (1) lost 20% of its efficiency after about 450 hours of heat treatment. The results suggested that using both a low bandgap polymer (e.g., polymer 3) and a relatively high bandgap polymer (e.g., P3HT) in the photoactive layer could significantly improve the lifetime of a photovoltaic cell.

Other embodiments are within the claims.

What is claimed is:

1. An article, comprising:
a first electrode;
a second electrode; and
a photoactive layer between the first and second electrodes, the photoactive layer comprising an electron donor material and an electron acceptor material;
wherein the electron donor material comprises a first polymer and a second polymer different from the first polymer, the first polymer comprises a first comonomer repeat unit containing a silacyclopentadithiophene moiety or a cyclopentadithiophene moiety and a second comonomer repeat unit containing a benzothiadiazole moiety, the second polymer comprises a monomer repeat unit containing a thiophene moiety, the first polymer has a first bandgap, the second polymer has a second bandgap higher than the first bandgap, and the article is configured as a photovoltaic cell.

2. The article of claim 1, wherein the first comonomer repeat unit in the first polymer comprises a silacyclopentadithiophene moiety of formula (1) or a cyclopentadithiophene moiety of formula (2): 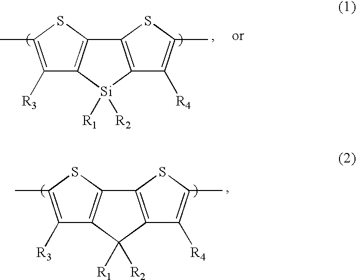
in which each of R₁, R₂, R₃, and R₄, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl.

3. The article of claim 2, wherein each of R₁ and R₂, independently, is H, C₁-C₂₀ alkyl, C₁-C₂₀ alkoxy, C₃-C₂₀ cycloalkyl, C₁-C₂₀ heterocycloalkyl, aryl, heteroaryl.

4. The article of claim 3, wherein each of R₁ and R₂, independently, is C₁-C₂₀ alkyl.

5. The article of claim 4, wherein each of R₁ and R₂ is 2-ethylhexyl or hexyl.

6. The article of claim 1, wherein the second comonomer repeat unit in the first polymer comprises a benzothiadiazole moiety of formula (3): 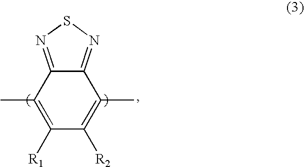
in which each of R₁ and R₂, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocyclo alkyl.

7. The article of claim 6, wherein each of R₁ and R₂, independently, is H.

8. The article of claim 1, wherein the first polymer further comprises a third comonomer repeat unit different from the first and second comonomer repeat units, and the third comonomer repeat unit comprises a silacyclopentadithiophene moiety or a cyclopentadithiophene moiety.

9. The article of claim 1, wherein the third comonomer repeat unit in the first polymer comprises a silacyclopentadithiophene moiety of formula (1) or a cyclopentadithiophene moiety of formula (2): 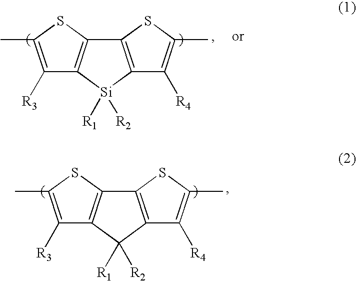
in which each of R₁, R₂, R₃, and R₄, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl.

10. The article of claim 1, wherein the first polymer comprises 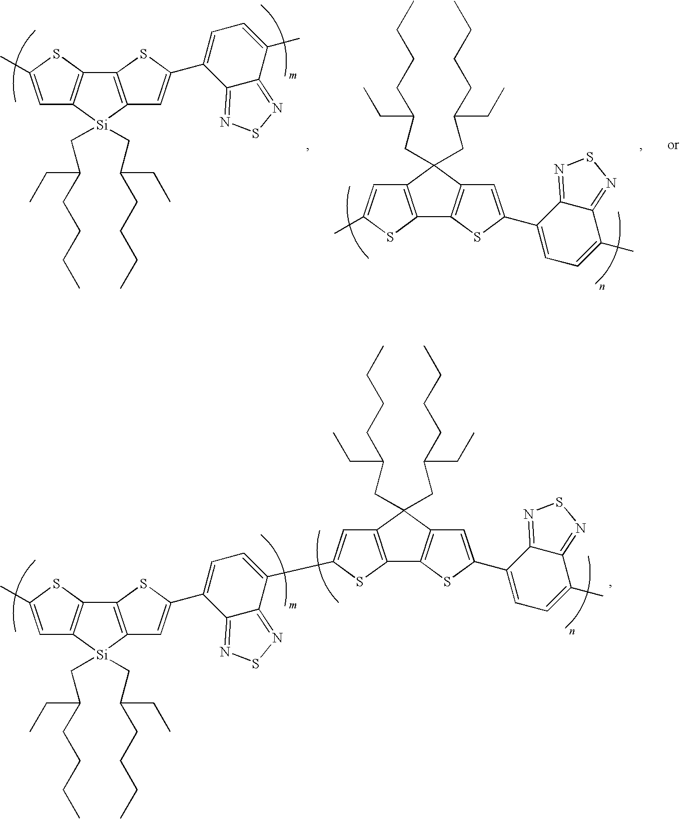
in which n is an integer from 1 to 1,000 and m is an integer from 1 to 1,000.

11. The article of claim 1, wherein the monomer repeat unit in the second polymer comprises a thiophene moiety of formula (4): 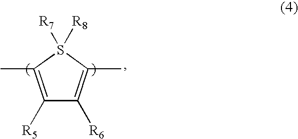
in which each of R₅, R₆, R₇, and R₈, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl.

12. The article of claim 11, wherein one of R₅ and R₆ is hexyl.

13. The article of claim 12, wherein the second polymer comprises poly(3-hexylthiophene).

14. The article of claim 1, wherein the electron acceptor material comprises a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

15. The article of claim 1, wherein the electron acceptor material comprises a substituted fullerene.

16. The article of claim 15, wherein the electron acceptor material comprises C60-PCBM, C70-PCBM, Bis-C60-PCBM, Bis-C70-PCBM.

17. The article of claim 1, wherein the weight ratio of the first and second polymers ranges from about 20:1 to about 1:20.

18. The article of claim 1, wherein the weight ratio of the first and second polymers is about 1:4.

19. The article of claim 1, wherein the first polymer, the second polymer, and the electron acceptor material has a first HOMO level, a second HOMO level, and a third HOMO level, respectively, and the first HOMO level is between the second and third HOMO levels.

20. The article of claim 1, wherein the first polymer, the second polymer, and the electron acceptor material has a first LUMO level, a second LUMO level, and a third LUMO level, respectively, and the first LUMO level is between the second and third LUMO levels.

21. The article of claim 1, wherein the weight ratio of the electron donor material and the electron acceptor material ranges from about 1:1 to about 1:3.

22. The article of claim 21, wherein the weight ratio of the electron donor material and the electron acceptor material is about 1:1.

23. The article of claim 1, wherein the photoactive layer has a thickness of at least about 150 nm.

24. The article of claim 1, wherein the article has a power conversion efficiency of at least about 4% under AM 1.5 conditions.

25. An article, comprising:
a first electrode;
a second electrode; and
a photoactive material between the first and second electrodes, the photoactive material comprising an electron donor material and an electron acceptor material;
wherein the electron donor material comprises a first polymer and a second polymer different from the first polymer, the first polymer comprises a first comonomer repeat unit containing a silacyclopentadithiophene moiety or a cyclopentadithiophene moiety and a second comonomer repeat unit containing a benzothiadiazole moiety, the first polymer has a first bandgap, the second polymer has a second bandgap higher than the first bandgap, and the article is configured as a photovoltaic cell.

26. The article of claim 25, wherein the second polymer comprises a monomer repeat unit containing a thiophene moiety.

27. An article, comprising:
a first electrode;
a second electrode; and
a photoactive layer between the first and second electrodes, the photoactive layer comprising an electron donor material and an electron acceptor material;
wherein the photoactive layer has a thickness of at least about 150 nm, the article is configured as a photovoltaic cell, and the article has a power conversion efficiency of at least about 4% under AM 1.5 conditions.

28. The article of claim 27, wherein the electron donor material comprises a first polymer and a second polymer different from the first polymer.

29. The article of claim 28, wherein the first polymer comprises a first comonomer repeat unit containing a silacyclopentadithiophene moiety or a cyclopentadithiophene moiety and a second comonomer repeat unit containing a benzothiadiazole moiety, and the second polymer comprises a monomer repeat unit containing a thiophene moiety.

30. The article of claim 29, wherein the first polymer further comprises a third comonomer repeat unit different from the first and second comonomer repeat units, and the third comonomer repeat unit comprises a silacyclopentadithiophene moiety or a cyclopentadithiophene moiety.
